(19) United States
(12) Patent Application Publication
(10) Pub. No.: US 2026/0182437 A1
(43) Pub. Date: Jun. 25, 2026

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Kazuaki NAGASAWA, Fukui (JP); Tomoshige CHIKAI, Tokyo (JP); Hidenari SATO, Oita (JP); Hisanori MATSUOKA, Fukui (JP); Hiroyuki TAKURA, Tokyo (JP)

(73) Assignee: Amkor Technology Singapore Holding Pte. Ltd., Valley Point #12-03 (SG)

(21) Appl. No.: 18/988,493

(22) Filed: Dec. 19, 2024

(51) Int. Cl. H01L 23/31; H01L 21/56; H01L 23/00; H01L 23/13; H01L 23/498

(52) U.S. Cl. CPC H10W 74/114; H10W 70/479; H10W 70/68; H10W 74/01; H10W 90/764

(57) ABSTRACT

In one example, an electronic device includes a substrate comprising a lower conductor, the lower conductor including a lower conductor lower side, which includes a perimeter. An electronic component is coupled to the substrate. An encapsulant covers a portion of the substrate and the electronic component, wherein the lower conductor lower side is exposed from the encapsulant. The electronic device includes one or more of a groove at the perimeter of the lower conductor lower side and extending inward from the lower conductor lower side with the encapsulant within the groove, or a protrusion in the encapsulant that extends to overlap the perimeter with the protrusion including a lower side that lies within a different horizontal plane than the lower conductor lower side. Other examples and related methods are also disclosed herein.

### CROSS REFERENCE TO RELATED APPLICATIONS

Not applicable.

### TECHNICAL FIELD

The present disclosure relates, in general, to electronic devices, and more particularly, to semiconductor devices and methods for manufacturing semiconductor devices

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIGS. 1A and 1B show top and bottom views, respectively, of an example electronic device.

FIG. 1C shows a cross-sectional view of the example electronic device taken along reference line 1C-1C of FIG. 1A and FIG. 1B.

FIG. 1D shows a partial cross-sectional view of an example electronic device.

FIGS. 2A, 2B, 2C, 2D, and 2E show cross-sectional views of an example method for manufacturing an example electronic device.

FIG. 3 shows a partial cross-sectional view of an example groove configuration.

FIG. 4 shows a cross-sectional view of an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and/or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements.

### DESCRIPTION

Epoxy mold compound (EMC) is used in some electronic packages to form encapsulated package bodies, which protect the electronic components contained therein. During a molding process, the EMC may inadvertently leak and migrate to portions of the electronic package where the EMC is not desired. Such portions can be referred to as keep-out zones. The leaking EMC is often referred to as mold flash and it can cause yield and reliability issues.

The present description includes, among other features, structures and associated methods that relate to electronic devices that are more resilient to manufacturing processes. More particularly, structures and methods are described to control the presence of mold flash and minimize any lateral flow of resin, including, but not limited to, lateral flow across an exposed surface of a conductive substrate. In some examples, grooves can be provided in a peripheral region of a lower side of a conductive substrate to reduce the lateral flow of the mold flash. In some examples, a recess can be provided in a mold structure to reduce the lateral flow of the mold flash. The recess provides an encapsulant with a bottom projection, which can overlap onto the periphery of the lower side of the conductive substrate. The structures and methods described hereinafter improve the yield and reliability of packaged electronic devices.

In an example, an electronic device includes a substrate comprising a lower conductor, the lower conductor including a lower conductor lower side, wherein the lower conductor lower side comprises a perimeter. An electronic component is coupled to the substrate. An encapsulant covers a portion of the substrate and the electronic component, wherein the lower conductor lower side is exposed from the encapsulant. The electronic device includes one or more of a groove at the perimeter of the lower conductor lower side and extending inward from the lower conductor lower side, wherein the encapsulant is within the groove; or a protrusion in the encapsulant that extends to overlap the perimeter, wherein the protrusion comprises a lower side that lies within a different horizontal plane than the lower conductor lower side.

In an example, an electronic device includes a substrate including a core layer comprising a core layer top side and a core layer lower side opposite to the core layer top side, an upper conductor over the core layer top side and comprising a first conductor and a second conductor, and a lower conductor over the core layer lower side and comprising a lower conductor lower side. An electronic component is coupled to the second conductor. A leadframe includes a first lead coupled to the electronic component, a second lead coupled to the second conductor, and a third lead coupled to the first conductor. An encapsulant covers the upper conductor and the electronic component. The lower conductor lower side comprises a perimeter, the lower conductor lower side is exposed from the encapsulant, and the encapsulant comprises a protrusion that extends to overlap the perimeter.

In an example, a method of making an electronic device includes providing a substrate including a core layer comprising a core layer top side and a core layer lower side opposite to the core layer top side, an upper conductor over the core layer top side and comprising a first conductor and a second conductor, and a lower conductor over the core layer lower side and comprising a lower conductor lower side. The method includes coupling an electronic component coupled to the second conductor. The method includes providing a leadframe comprising a first lead, a second lead, and third lead. The method includes coupling the first lead the electronic component. The method includes coupling the second lead to the second conductor. The method includes coupling the third lead to the first conductor. The method includes providing an encapsulant covering the upper conductor and the electronic component. The lower conductor lower side comprises a perimeter, the lower conductor lower side is exposed from the encapsulant, and the encapsulant comprises a protrusion that extends to overlap the perimeter.

Other examples are included in the present disclosure. Such examples may be found in the figures, in the claims, or in the description of the present disclosure.

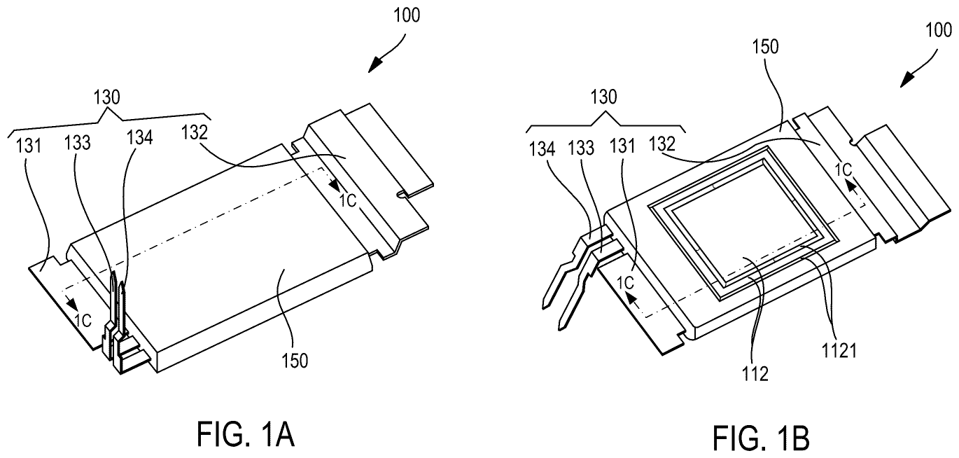

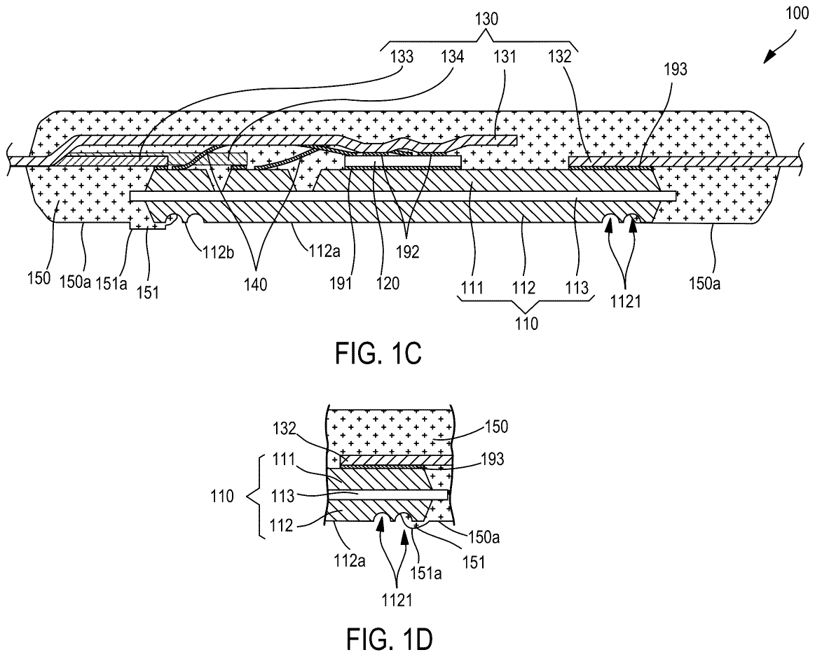

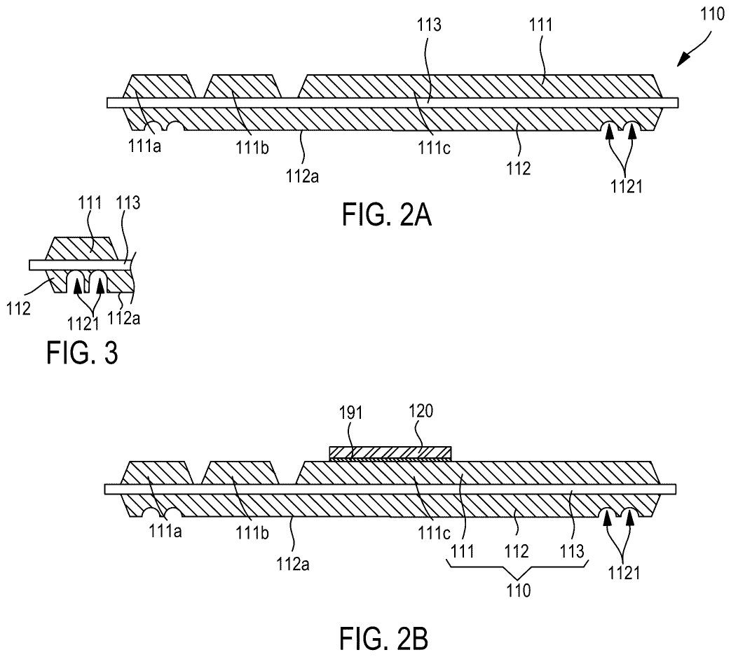

FIGS. 1A and 1B show top and bottom views of an example electronic device 100 respectively, and FIG. 1C shows a cross-sectional view of electronic device 100 taken along reference line 1C-1C of FIGS. 1A and 1B. In the examples shown in FIGS. 1A, 1B, and 1C, electronic device 100 can comprise substrate 110, electronic component 120, leadframe 130, component interconnects 140, and encapsulant 150. In some examples, electronic device 100 can further comprise die bonding layer 191, leadframe bonding layer 192, and leadframe bonding layer 193. Electronic device 100 can comprise or be referred to as a packaged electronic device, a packages electronic structure, or a packaged semiconductor device.

Substrate 110 can comprise upper conductor 111, lower conductor 112, and core layer 113. In some examples, core layer 113 comprises a core layer top side and a core layer lower side opposite to the core layer top side, and upper conductor can be over the core layer top side and lower conductor can be over the core layer lower side. Lower conductor 112 can further comprise one or more grooves 1121 provided on a lower conductor lower side 112a, which extends inward from lower conductor lower side 112a. In some examples, grooves 1121 are at a perimeter of lower conductor lower side 112a.

In some examples, leadframe 130 can comprise source lead 131, drain lead 132, gate lead 133, and sensor lead (optional) 134. Source lead 131 can be an example of a first lead, drain lead 32 can be example of a second lead, gate lead 133 can be an example of a third lead, and sensor lead 134 can be an example of a fourth lead. Although only a portion of leadframe 130 is shown in FIG. 1C, a portion of leadframe 130 outside encapsulant 150 can be folded upward or downward, as shown in FIGS. 1A and 1B. In some examples, as shown in FIG. 1B, when electronic device 100 is mounted to a next level of assembly, such as an external device, lower conductor 112 faces outward or upward and the outer portion of leadframe 130 (for example, gate lead 133 and sensor lead 134) can be folded downward. In some examples, gate lead 133 is bent in a direction opposite to lower conductor lower side 112a.

In some examples, encapsulant 150 can comprise protrusion 151 that protrudes downward and covers or overlaps onto the perimeter of lower conductor lower side 112a (for example, left side of FIG. 1C). In other examples, protrusion 151 is not included and instead, lower side 150a of encapsulant 150 can be substantially coplanar with lower conductor lower side 112a (for example, right side of FIG. 1C). In accordance with the present description, grooves 1121 in lower conductor lower side 112a can restrain or trap mold flash (for example, resin) that flows during the molding process to provide encapsulant 150 thereby reducing the likelihood that the mold flash encroaches onto lower conductor lower side 112a. This avoids an unwanted decrease in surface area of lower conductor 112 exposed from encapsulant 150. Protrusion 151 can comprise or be referred to as a bottom projection.

In some examples, protrusion 151 extends below lower conductor lower side 112a so that lower conductor lower side 112a and lower side 151a of protrusion 151 lie within different horizonal planes. In some examples, lower conductor lower side 112a is recessed inward from lower side 151a of protrusion 151. In some examples, lower side 151a of protrusion lies within a different horizontal plane than a lower side 150a of encapsulant 150. In some examples, protrusion 151 surrounds the perimeter of lower conductor lower side 112a. In some examples, protrusion 151 surrounds the perimeter of lower conductor lower side 112a without breaks. In some examples, a portion 112b of lower conductor 112 is interposed between grooves 1121. In some examples, portion 112b can be devoid of encapsulant 150.

FIG. 1D illustrates a partial cross-sectional view of electronic device 100 where lower side 151a of protrusion 151 comprises a rounded shape proximate to where protrusion overlap lower conductor 112. In the example of FIG. 1Ca, protrusion 151 further extends into at least one of grooves 1121.

Substrate 110, leadframe 130, component interconnects 140, and encapsulant 150 can be referred to as an electronic package, and the electronic package provides protection for electronic component 120 from external elements and/or external exposure. Additionally, the electronic package provides electrical coupling between external electronic components and electronic component 120.

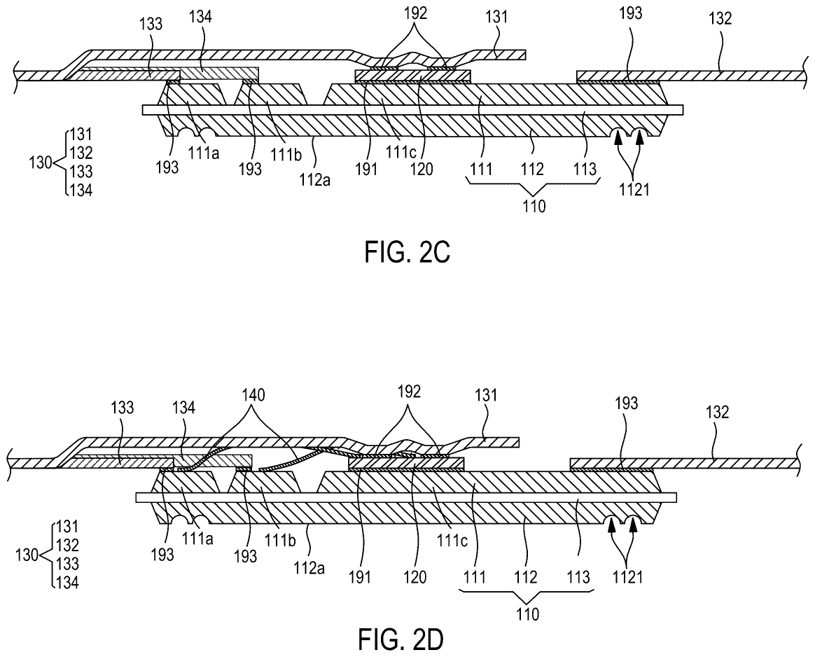

FIGS. 2A, 2B, 2C, 2D, and 2E show cross-sectional views of an example method for manufacturing an electronic device. In some examples, the method of FIGS. 2A-2E can be used to make or form electronic device 100. FIG. 2A shows a cross-sectional view of example electronic device 100 at an early stage of manufacture.

In the example shown in FIG. 2A, substrate 110 can be provided. In some examples, substrate 110 can comprise or be referred to as an active metal brazing (AMB) board or a direct copper bonding (DCB) board. The AMB board can be manufactured by bonding a copper plate to the surface of a ceramic plate that acts as an insulator. In some examples, the AMB board is used in power module applications and can provide more stable electrical connections. The DCB board can also include a ceramic substrate that acts as an insulator and a copper connection that ensures conductivity at high temperatures. The DCB board can be used as a substrate for power modules and can provide improved reliability and performance.

In some examples, substrate 110 comprises upper conductor 111, lower conductor 112, and core layer 113. Upper conductor 111 can comprise or be referred to as a patterned conductive layer, such as copper or a metal foil. The thickness of upper conductor 111 can range from about 1 micron (μm) to about 500 μm. Upper conductor 111 can provide a current flow path between electronic component 120 and leadframe 130. In the present example, upper conductor 111 can comprise a gate conductor 111a, a sensor conductor 111b, and a drain conductor 111c. Gate conductor 111a can be an example of a first conductor or first conductive pattern, drain conductor 111c can be an example of a second conductor or a second conductive pattern, and sensor conductor 111b can be an example of a third conductor or a third conductive pattern.

Lower conductor 112 can comprise or be referred to as a metal layer, such as copper or a metal foil. In some examples, lower conductor 112 can comprise a solid or uninterrupted metal layer. In some examples, lower conductor 112 can comprise a patterned metal layer. The thickness of lower conductor 112 can range from about 1 μm to about 500 μm. In some examples, lower conductor 112 can provide a current flow path between electronic component 120 and leadframe 130. In some examples, lower conductor 112 can provide a heat sink or a heat transfer path for electronic device 100.

In the present example, core layer 113 comprises an insulator. In some examples, core layer 113 can comprise a ceramic or dielectric material. In some examples, core layer 113 can comprise aluminum oxide (Al₂O₃), aluminum nitride (AlN), silicon nitride (SiN), beryllium oxide (BeO), combinations thereof, or other materials as known to one of ordinary skill in the art. In some examples, substrate 110 can comprise vias penetrating core layer 113 that couple upper conductor 111 and lower conductor 112. In some examples, the thickness of core layer 113 can range from about 100 μm to about 2000 μm. Core layer 113 provides support for upper conductor 111 and lower conductor 112. In some examples, the area of substrate 110 can range from about 5 mm×5 mm to about 60 mm×60 mm, and the thickness of substrate 110 can range from about 100 μm to about 3000 μm.

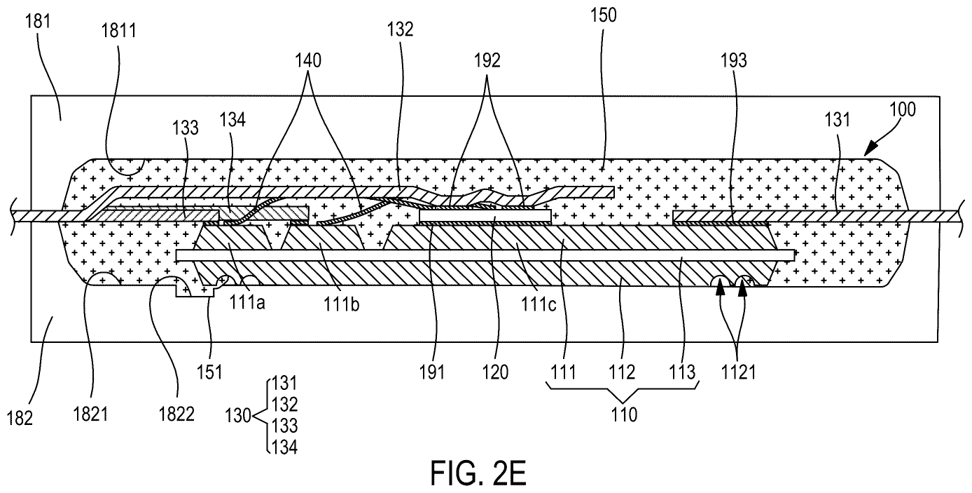

In accordance with the present description, substrate 110 comprises one or more grooves on lower conductor lower side 112a, which extend inward into lower conductor 112. In some examples, grooves 1121 are provided proximate to the perimeter or peripheral region or area of lower conductor 112 thereby leaving the inward or central portion of lower conductor 112 devoid of grooves 1121. Grooves 1121 can comprise or be referred to as dimples, recesses, channels, or trenches. In some examples, grooves 1121 can be continuous around the periphery of lower conductor 112 without breaks. In some examples, grooves can be discrete or individual structures separated by spaces or portions of lower conductor lower side 112a. In some examples, grooves 1121 can be provided in at least two rows or more. In some examples, grooves 1121 can be provided to be spaced about 1μm to about 500μm apart from each other from the periphery of lower conductor 112. The distance between grooves 1121 may range from about 1μm to about 500μm. The depth of the grooves 1121 can range from about 1μm to about 500 μm.In some examples, grooves 1121 terminate within lower conductor 112. In some examples, grooves 1121 can extend to and terminate at core layer 113 so that a portion of core layer 113 is exposed from grooves 1121 as shown in FIG. 3. In some examples, the cross-sectional shape of the grooves 1121 can be triangular, rounded, square, or semicircular.

Grooves 1121 can reduce the occurrence of escaped resin or mold flash, which is an unwanted component that can occur during the molding process to form encapsulant 150, from flowing across grooves 1121 onto lower conductor lower 112a. Mold flash can occur when resin is pushed out from surfaces of the mold structure. For example, mold flash can occur due to various causes including, but not limited to, excessively high injection pressure, poor precision of the mold structure, wear of the mold structure, or low viscosity of resin. If mold flash occurs to an excessive extent or exceeds a reference value, a process for removing the mold flash must be added to the manufacturing process of a device. This adds manufacturing costs and increases manufacturing cycle time. In addition, excessive mold flash can cause defects and reliability issues to the electronic device. In accordance with the present description grooves 1121 can restrain or impede the flow of excessive mold flash, thereby suppressing the defect from occurring in the device. For example, when grooves 1121 comprise at least two grooves, mold flash can fill an outer one of grooves 1121, which is close to the edge of lower conductor 112 to impede the flow, or mold flash can fill an inner one of grooves 1121 to further impedes the flow, thereby preventing the mold flash from contaminating the lower conductor lower side 112a.

FIG. 2B shows a cross-sectional view of example electronic device 100 at a later stage of manufacture. In the example shown in FIG. 2B, electronic component 120 can be provided.

Electronic component 120 can comprise or be referred to as a power component, a power device, a metal-oxide semiconductor field-effect transistor (MOSFET), an insulated gate bipolar transistor (IGBT), a thyristor, a silicon carbide (SiC) power device, a SiC semiconductor, a SiC power semiconductor, a diode, a transistor, a transistor, a semiconductor die, a semiconductor chip, or a semiconductor package. In some examples, electronic component 120 can comprise component terminals provided on the upper and lower sides, respectively. In some examples, an upper component terminal can comprise a source terminal, a gate terminal, or a sensor terminal, and a lower component terminal can comprise a drain terminal. The area of electronic component 120 can range from about 1 mm×1 mm to about 20 mm×20 mm, and the thickness of electronic component 120 can range from about 30 μm to about 750 μm. In some examples, electronic component 120 can function as a switch that supplies power and converts it into power suitable for a product that uses the converted power. In some examples, electronic component 120 can switch power of about tens to hundreds of volts or tens of amperes.

In some examples, electronic component 120 can comprise a digital signal processor (DSPs), a network processor, a power management unit, an audio processor, a wireless baseband system on a chip (SoC) processor, a sensor, an application specific integrated circuit, a memory, an antenna on package (AoP), an antenna in package (AiP), a 5G NR mmWave module, a sub- 6 GHz RF module or an Integrated passive device (IPD). Electronic component 120 can perform various calculations and control processing, store data, remove noise from an electrical signal, transmit/receive radio frequencies or amplifying electrical current or voltage. It is understood that multiple electronic components 120 can be provided on substrate 110.

Electronic component 120 can be coupled including bonded or attached to upper conductor 111 of substrate 110 using die bonding layer 191. In some examples, die bonding layer 191 can be provided between the lower component terminal (for example, the drain terminal) of electronic component 120 and upper conductor 111 of substrate 110. In the present example, electronic component 120 can be coupled to drain conductor 111c with die bonding layer 191.

In some examples, die bonding layer 191 can comprise a sintering material, and the sintering material can be provided on upper conductor 111. The sintering material can be provided on upper conductor 111 by a coating method such as spin coating, doctor blade coating, casting, painting, spray coating, slot die coating, curtain coating, slide coating, or knife over edge coating, a printing method such as screen printing, pad printing, gravure printing, flexography printing, or offset printing, or an inkjet printing method, or an intermediate technology between coating and printing, or can be provided by direct attachment of a bonding film or a bonding tape. In some examples, the sintering material may include a sintering paste, a sintering film, or a sintering tape comprising sinterable metal particles and a solder material that can melt at a lower temperature than the metal particles.

The metal particles can comprise a solderless material. In some examples, the metal particles can comprise silver (Ag), gold (Au), copper (Cu), nickel (Ni), or aluminum (Al) particles. In some examples, the metal particles can comprise nanoscale or microscale particles. In some examples, the metal particles can have a particle size ranging from about 1 nanometer (nm) to about 10 μm. In other examples, the metal particles can have a particle size greater than about 10 μm. The solder material can comprise a tin (Sn) based solder, a lead (Pb) based solder, or a Au-based solder. In some examples, the Sn-based solder (lead free solder) can comprise pure Sn, Sn—Ag, Sn—Ag—Cu, or Sn—Cu. In some examples, the Pb-based solder (flexible solder) can comprise Sn-Pb. In some examples, the Au-based solder (hard solder) can comprise Au—Sn. The solder material can comprise Sn as a main component material. In some examples, the content of Sn in the solder material can be higher than about 90 weight percent (wt%). However, the specific composition and composition ratio of the solder material can vary.

The sintering material can be a mixture paste in which the content ratio (weight ratio) of the solder material and the metal particles can be higher than about 1:2.5. In some examples, the content ratio (weight ratio) of the solder material and the metal particles in the mixture paste can range from about 1:3 to about 1:10. When the content (wt%) of the metal particles is about 2.5 times or about 3 times more than the content (wt %) of the solder material, an intermetallic compound by the reaction therebetween can be more reliably formed. Depending on the types of solder material and metal particles and the type of intermetallic compound to be formed, the content ratio of the solder material and metal particles can vary. In some examples, the mixture paste can further comprise a binder or a solvent in addition to the metal particles and the solder material. The thickness of the sintering material applied on upper conductor 111, that is, the mixture paste, can range from about 10 μm to about 100 μm. In some examples, the thickness of the sintering material can range from about 15 μm to about 30 μm. The sintering material or mixture paste can temporarily attach the lower terminal of electronic component 120 to upper conductor 111 of substrate 110.

Subsequently, a sintering process can be performed. In some examples, the sintering process can be performed in a state in which the lower terminal of electronic component 120 is temporarily brought into contact with the mixture paste provided on upper conductor 111 of substrate 110. The sintering process can comprise a heating process. In some examples, by providing a temperature higher than the melting point of the solder material in the mixture paste, the sintering process for the metal particles and the soldering process for the solder material in the mixture paste can be performed simultaneously. Through this, at the same time as the metal particles are sintered, the metal particles and the solder material can react to form an intermetallic compound. In some examples, the heating temperature during the sintering process can range from about 150° C. to about 300° C.

By the sintering process, die bonding layer 191 can be formed between electronic component 120 and substrate 110. In some examples, die bonding layer 191 can be provided between the lower component terminal of electronic component 120 and drain conductor 111c of substrate 110, and thus the lower component terminal of electronic component 120 can be coupled to upper conductor 111 of substrate 110. Die bonding layer 191 can comprise the intermetallic compound formed by the reaction between the metal particles and the solder material. In some examples, when the metal particles comprise Ag particles and the solder material comprises Sn, an intermetallic compound including Ag₃Sn can be formed by the reaction therebetween. In some examples, the content of the intermetallic compound in die bonding layer 191 can be greater than about 50 wt% or about 60 wt%. The intermetallic compound can be uniformly or relatively uniformly distributed throughout die bonding layer 191. The final thickness of die bonding layer 191 can range from about 10 μm to about 100 μm. In some examples, the final thickness of die bonding layer 191 can range from about 15 μm to about 30 μm.

FIG. 2C shows a cross-sectional view of example electronic device 100 at a later stage of manufacture. In the example shown in FIG. 2C, leadframe 130 can be provided.

In some examples, leadframe 130 can comprise source lead 131, drain lead 132, gate lead 133, and sensor lead 134. In the present example, gate lead 133 and sensor lead 134 are also shown in FIGS. 1A and 1B external to or exposed from encapsulant 150. In some examples, when electronic component 120 does not comprise a sensor terminal, sensor lead 134 can be omitted. In some examples, source lead 131 can be positioned on the source terminal of electronic component 120 through leadframe bonding layer 192. In some examples, drain lead 132 can be positioned on upper conductor 111 (for example, drain conductor 111c) of substrate 110 through leadframe bonding layer 193. In some examples, gate lead 133 can be positioned on upper conductor 111 (for example, gate conductor 111a) of substrate 110 through leadframe bonding layer 193. In some examples, sensor lead 134 can be positioned on upper conductor 111 (for example, sensor conductor 111b) of substrate 110 through leadframe bonding layer 193. In some examples, leads 131-134 can comprise or be referred to as input/output pins or input/output legs. In some examples, one or more leads 131-134 can be bent at least once, and some portions of the leads can be positioned inside encapsulant 150 and other portions thereof can be exposed from or protrude outward from encapsulant 150.

In some examples, leadframe 130 comprises a conductive material, such as a copper alloy or an iron alloy. Leadframe 130 can be manufactured by chemically etching or mechanically stamping a metal strip. Leadframe 130 can provide an electrical path (for example, a signal path or a power path) between electronic component 120 and a next level of assembly, such as an external board. In some examples, the area of leadframe 130 can range from about 5 millimeters (mm)×5 mm to about 60 mm×60 mm, and the thickness of substrate 110 can range from about 100 μm to about 1000 μm.

In some examples, leadframe bonding layer 192 and leadframe bonding layer 193 can comprise a sintering material similar to or identical to die bonding layer 191, and thus the method for electrically connecting leadframe 130 to electronic component 120 and substrate 110 can also be similar to the method described with FIG. 2B.

In some examples, leadframe bonding layer 192 can be provided on the source terminal of electronic component 120, and leadframe bonding layer 193 can be provided on upper conductor 111. In some examples, leadframe bonding layer 192 can be provided on source lead 131, and leadframe bonding layer 193 can be provided on drain lead 132. Thereafter, source lead 131 can be electrically connected to electronic component 120 and drain lead 132 can be electrically connected to substrate 110 in a manner similar or identical to the method for interconnecting substrate 110 and electronic component 120 through die bonding layer 191 comprising a sintering material. In a similar manner, source lead 131 and drain lead 132 can be electrically connected to electronic component 120 and substrate 110 respectively.

In some examples, leadframe bonding layer 192 and leadframe bonding layer 193 can comprise a Sn-based solder, a Pb-based solder, or an Au-based solder. Accordingly, source lead 131 and drain lead 132 can be electrically connected to electronic component 120 and substrate 110, respectively, through a reflow process.

FIG. 2D shows a cross-sectional view of example electronic device 100 at a later stage of manufacture. In the example shown in FIG. 2D, component interconnects 140 can be provided.

Component interconnects 140 can electrically connect substrate 110 and electronic component 120. Component interconnects 140 can electrically connect upper conductor 111 of substrate 110 (for example, a gate conductor 111a having gate lead 133 coupled thereto) and the gate terminal of electronic component 120. Component interconnects 140 can electrically connect upper conductor 111 of substrate 110 (for example, a sensor conductor 111b having sensor lead 134 coupled thereto) and the sensor terminal of electronic component 120. Component interconnects 140 can comprise conductive wires or conductive tabs.

In some examples, component interconnects 140 can comprise conductive wires, such as gold wires, copper wires, or aluminum wires. In some examples, one end of each of component interconnects 140 can be ball-bonded to the gate terminal of electronic component 120 by wire bonding equipment, and the other end of each of component interconnects 140 can be stitch-bonded to upper conductor 111 of substrate 110 (for example, gate conductor 111a having gate lead 133 coupled thereto). The reverse is also possible. In some examples, one end of each of component interconnects 140 can be ball bonded to the sensor terminal of electronic component 120 by wire bonding equipment, and the other end of each of component interconnects 140 can be stitch-bonded to upper conductor 111 of substrate 110 (for example, sensor conductor 111b having sensor lead 134 coupled thereto). The reverse is also possible.

In some examples, component interconnects 140 can comprise conductive clips, such as copper clips or aluminum clips. In some examples, one end of each of component interconnects 140 can be soldered to the gate terminal of electronic component 120 and the other end of each of component interconnects 140 can be soldered to upper conductor 111 of substrate (110) (for example, gate conductor 111a having gate lead 133 coupled thereto). In some examples, one end of each of component interconnects 140 can be soldered to the sensor terminal of electronic component 120 and the other end of each of component interconnects 140 can be soldered to upper conductor 111 of substrate 110 (for example, sensor conductor 111b having sensor lead 134 coupled thereto).

In some examples, the lengths of component interconnects 140 can range from about 1 mm to about 20 mm, and the diameters or thicknesses of component interconnects 140 can range from about 20 μm to about 500 μm. Component interconnects 140 can provide a current flow path between electronic component 120 and gate lead 133 and between electronic component 120 and sensor lead 134.

FIG. 2E shows a cross-sectional view of example electronic device 100 at a later stage of manufacture. In the example shown in FIG. 2E, encapsulant 150 can be provided.

Electronic device 100 having substrate 110, electronic component 120, leadframe 130, and component interconnects 140, which can comprise or be referred to as a subassembly, can be clamped between upper mold 181 and lower mold 182.

In some examples, upper mold 181 can comprise upper cavity 1811 that is recessed in an upward direction, lower mold 182 can comprise lower cavity 1821 that is recessed in a downward direction, and electronic device 100 can be placed and clamped between upper cavity 1811 and lower cavity 1821.

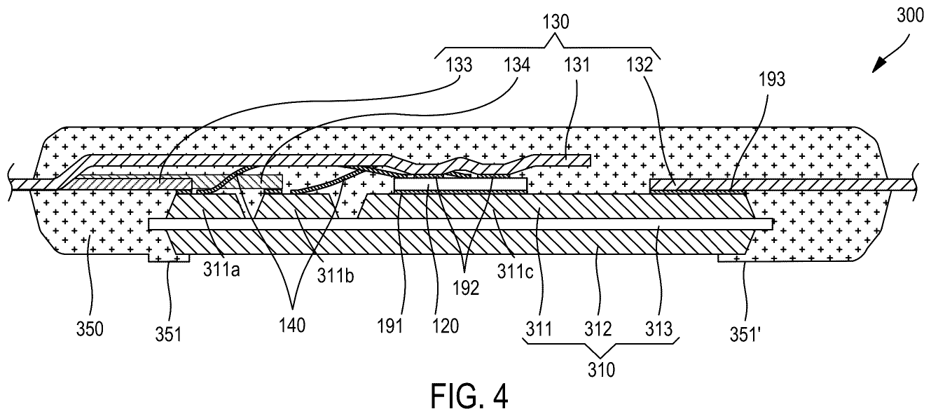

In some examples, lower conductor 112 of substrate 110 can be in contact with the bottom surface of lower cavity 1821. In some examples, the bottom surface of lower cavity 1821 can comprise lower sub-cavity 1822 that is further recessed in a downward direction in an area corresponding to the perimeter of lower conductor 112. In some examples, lower sub-cavity 1822 can be adjacent to grooves 1121 of lower conductor 112. In other examples, lower sub-cavity 1822 can be used without grooves 1121 as described with FIG. 4. In which case the perimeter of lower conductor lower side 112a is adjacent to lower sub-cavity 1822.

Encapsulant 150 can be provided between upper cavity 1811 of upper mold 181 and lower cavity 1821 of lower mold 182. In some examples, molten encapsulant 150 can flow into upper cavity 1811 and lower cavity 1821 through a gate (or a supply port) provided in upper mold 181 or lower mold 182. In this way, encapsulant 150 can surround substrate 110, electronic component 120, leadframe 130, and component interconnects 140. In some examples, during the step of providing encapsulant 150, encapsulant 150 can also flow into lower sub-cavity 1822, whereby mold flash of encapsulant 150 can fill lower sub-cavity 1822 or grooves 1121 provided in lower conductor 112. Lower sub-cavity 1822 or grooves 1121 constrain the flow of mold flash from encapsulant 150. Accordingly, the mold flash no longer flows in a horizontal direction toward lower conductor 112. In some examples, encapsulant 150 can surround the lower periphery of lower conductor 112, and thus encapsulant 150 can comprise protrusion 151 that protrudes downward. In some examples, lower sub-cavity 1822 can be omitted as illustrated on the right side of FIG. 2E, and thus protrusion 151 may not be provided.

Electronic device 100 provided with encapsulant 150 can be removed from upper mold 181 and lower mold 182. In some examples, after encapsulant 150 has cured, upper mold 181 and lower mold 182 can be separated from each other, and electronic device 100 can be separated from upper mold 181 or lower mold 182.

In this way, in the present invention, electronic device 100 can be provided with lower conductor 112 of substrate 110 exposed from encapsulant 150. In some examples, one or more grooves 1121 can also be exposed at the same time as lower conductor 112 is exposed. In addition, as described above, protrusion 151 can be provided around the periphery of lower conductor 112.

In some examples, protrusion 151 can be omitted. In some examples, the lower side of encapsulant 150 can be substantially coplanar with lower conductor lower side 112a as shown at the right side of electronic device 100 in FIG. 2E. Even in this case, the mold flash is trapped in grooves 1121, and thus the mold flash does not excessively flow to lower conductor lower side 112a. In this way, encapsulant 150 can surround substrate 110, electronic component 120, leadframe 130, and component interconnects 140 and a portion of substrate 110, for example, lower conductor lower side 112a, can be exposed from encapsulant 150. A portion of leadframe 130 can be positioned inside encapsulant 150, and the remaining portion of leadframe 130 can be positioned outside encapsulant 150. In some examples, encapsulant 150 can be in the outer most one of grooves 1121 and the inter most one of grooves 1121 can be devoid of encapsulant 150.

Encapsulant 150 can comprise or be referred to as an epoxy mold compound, a resin, a filler-reinforced polymer, a B-stage compression film, or gel. In some examples, encapsulant 150 can be provided by transfer molding, compression molding, liquid body molding, vacuum lamination, paste printing, or film-assisted molding. As described above, transfer molding can comprise a process of supplying a resin to the vicinity of substrate 110 by using a gate (a supply port), and compression molding can comprise a process of supplying a fluid resin to a mold in advance and then putting substrate 110 into the mold to cure the fluid resin After this process, cured encapsulant 150 can be ejected from the mold. The area of encapsulant 150 can range from about 5 mm×5 mm to about 70 mm×70 mm, and the thickness of encapsulant 150 can range from about 0.9 mm to about 10 mm. Encapsulant 150 can isolate and protect substrate 110, electronic component 120, leadframe 130, and component interconnects 140 from external hostile environments.

In this way, even though electronic device 100 according to the present invention is an exposed substrate exposure package, excessive mold flash may not be generated from encapsulant 150. For example, since the mold flash is trapped in grooves 1121 provided in lower conductor 112 of substrate 110, the mold flash does not excessively flow downward from lower conductor 112. Accordingly, in the present invention, the mold flash exists only at a specified position and does not excessively flow in an irregular downward direction, thereby preventing various defects from occurring during the device manufacturing process.

FIG. 4 shows a cross-sectional view of an example electronic device 300. In the examples shown in FIG. 4, electronic device 300 can comprise substrate 310, electronic component 120, leadframe 130, component interconnects 140, and encapsulant 350. Electronic device 300 shown in FIG. 3 can have similarities to electronic device 100 shown in FIG. 1C, and only differences will be described in hereinafter. Substrate 310 can comprise upper conductor 311, lower conductor 312, and core layer 313. In some examples, upper conductor 311 comprises gate conductor 311a, sensor conductor 311b, and drain conductor 311c. Lower conductor 312 can have a generally flat lower side and may not have a groove. Encapsulant 350 can further comprise protrusion 351 that surrounds and overlaps onto the perimeter of lower conductor 312. Protrusion 351 can cover the inner and outer sides with respect to the lower perimeter of lower conductor 312. In accordance with the present description, protrusion 351 can be provided using lower sub-cavity 1822 in lower mold 182. In other examples, a protrusion 351′ comprising a larger width can be provided by increasing the width of lower sub-cavity 1822. Protrusions 351 and 351′ can comprise or be referred to as bottom projections.

In some examples, the thickness of the protrusions 351 can range from about 1 μm to about 1000 μm. In some examples, the width of protrusion 351, for example, the width of protrusion 351 extending inwardly from the lower periphery of lower conductor 312, can range from about 1 μm to about 1000 μm. With these thicknesses and width dimensions of protrusion 351, the amount of mold flash is reduced and controlled during the process of providing encapsulant 350. The resin, which is the main material of encapsulant 350, can constitute protrusion 351. In some examples, the mold flash may not flow excessively into the inner side of lower conductor 312 of substrate 310 because of protrusion 351.

In summary, structures and methods have been described that relate to packaged electronic components having improved manufacturability, quality, and reliability. More particularly, structures and methods have been described to control the presence of mold flash and minimize any lateral flow of resin, including, but not limited to, lateral flow across an exposed surface of a conductive substrate. In some examples, grooves are provided in a peripheral region of a lower side of a conductive substrate to reduce the lateral flow of the mold flash. In some examples, a recess is provided in a mold structure to reduce the lateral flow of the mold flash. The recess provides an encapsulant with a protrusion, which can overlap onto the lower side of the conductive substrate. The structures and method described herein improve the yield and reliability of packaged electronic devices.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

What is claimed is:

1. An electronic device, comprising:
a substrate comprising a lower conductor, the lower conductor including a lower conductor lower side, wherein the lower conductor lower side comprises a perimeter;
an electronic component coupled to the substrate;
an encapsulant covering a portion of the substrate and the electronic component, wherein the lower conductor lower side is exposed from the encapsulant; and
one or more of:
a groove at the perimeter of the lower conductor lower side and extending inward from the lower conductor lower side, wherein the encapsulant is within the groove; or
a protrusion in the encapsulant that extends to overlap the perimeter, wherein the protrusion comprises a lower side that lies within a different horizontal plane than the lower conductor lower side.

2. The electronic device of claim 1, wherein the electronic device comprises:
the groove at the perimeter of the lower conductor lower side, but not the protrusion.

3. The electronic device of claim 2, further comprising:
a second groove at the perimeter of the lower conductor lower side and laterally separated from the groove by a portion of the lower conductor lower side.

4. The electronic device of claim 1, further comprising:
a leadframe comprising:
a first lead coupled to the electronic component;
a second lead; and
a third lead;
wherein:
the substrate comprises:
a core layer comprising an insulator, a core layer top side, and a core layer lower side opposite to the core layer top side; and
an upper conductor over the core layer top side and comprising a first conductor and a second conductor;
the lower conductor is over the core layer lower side;
the second lead is attached to the second conductor;
the electronic component is attached to the second conductor with a sintering material;
the third lead is attached to the first conductor; and
the second lead and the third lead are exposed from the encapsulant.

5. The electronic device of claim 1, wherein the electronic device comprises:
the protrusion in the encapsulant, but not the groove.

6. The electronic device of claim 5, wherein:
the encapsulant comprises a lower side; and
the lower side of the protrusion extends downward from the lower side of the encapsulant.

7. The electronic device of claim 5, wherein:
the protrusion surrounds the perimeter of the lower conductor lower side.

8. The electronic device of claim 1, wherein the electronic device comprises:
the groove at the perimeter of the lower conductor lower side; and
the protrusion in the encapsulant;
wherein:
the encapsulant in the groove comprises a portion of the protrusion.

9. An electronic device, comprising:
a substrate comprising:
a core layer comprising a core layer top side and a core layer lower side opposite to the core layer top side;
an upper conductor over the core layer top side and comprising a first conductor and a second conductor; and
a lower conductor over the core layer lower side and comprising a lower conductor lower side;
an electronic component coupled to the second conductor;
a leadframe comprising:
a first lead coupled to the electronic component;
a second lead coupled to the second conductor; and
a third lead coupled to the first conductor; and
an encapsulant covering the upper conductor and the electronic component; wherein:
the lower conductor lower side comprises a perimeter;
the lower conductor lower side is exposed from the encapsulant; and
the encapsulant comprises a protrusion that extends to overlap the perimeter.

10. The electronic device of claim 9, further comprising:
a groove at the perimeter of the lower conductor lower side and extending inward from the lower conductor lower side towards the core layer;
wherein:
the protrusion extends into the groove.

11. The electronic device of claim 10, wherein:
the groove is one of a plurality of grooves at the perimeter of the lower conductor lower side; the plurality of grooves are separated by a portion of the lower conductor lower side; and
the portion is devoid of the encapsulant.

12. The electronic device of claim 10, wherein:
the groove extends to the core layer lower side.

13. The electronic device of claim 9, wherein:
the protrusion surrounds the perimeter of the lower conductor lower side.

14. The electronic device of claim 9, wherein:
the first lead, the second lead, and the third lead are exposed from the encapsulant; and
the third lead is bent in a direction opposite to the lower conductor lower side.

15. The electronic device of claim 9, wherein:
the core layer comprises a ceramic.

16. The electronic device of claim 9, further comprising:
a component interconnect coupled to the electronic component and coupled to the second conductor, wherein the encapsulant covers the component interconnect.

17. The electronic device of claim 9, wherein:
the substrate comprises an active metal brazing (AMB) board.

18. A method of making an electronic device, comprising:
providing a substrate comprising:
a core layer comprising a core layer top side and a core layer lower side opposite to the core layer top side;
an upper conductor over the core layer top side and comprising a first conductor and a second conductor; and
a lower conductor over the core layer lower side and comprising a lower conductor lower side;
coupling an electronic component coupled to the second conductor;
providing a leadframe comprising a first lead, a second lead, and third lead;
coupling the first lead the electronic component;
coupling the second lead to the second conductor;
coupling the third lead to the first conductor; and
providing an encapsulant covering the upper conductor and the electronic component, wherein:
the lower conductor lower side comprises a perimeter;
the lower conductor lower side is exposed from the encapsulant; and
the encapsulant comprises a protrusion that extends to overlap the perimeter.

19. The method of claim 18, wherein:
providing the substrate comprises providing a groove at the perimeter of the lower conductor lower side and extending inward from the lower conductor lower side towards the core layer; and
providing the encapsulant comprises providing a portion of the protrusion extending into the groove.

20. The method of claim 19, wherein:
providing the encapsulant comprises:
providing an upper mold comprising an upper cavity;
providing a lower mold comprising a lower cavity, a bottom surface, and a sub-cavity in the bottom surface;
placing the substrate, the electronic component, and the leadframe between the upper mold and the lower mold so that the lower conductor lower side of the lower conductor contacts the bottom surface of the lower mold and the perimeter of the lower conductor lower side and the groove are adjacent to the sub-cavity;
providing the encapsulant between the upper cavity and the lower cavity to cover the upper conductor and the electronic component; and
providing the encapsulant into the sub-cavity to provide the protrusion; and
the sub-cavity and the groove constrain flow of mold flash from the encapsulant during the step of providing the encapsulant.
